(19) United States
(12) Patent Application Publication
(10) Pub. No.: US 2008/0013458 A1
(43) Pub. Date: Jan. 17, 2008

(54) Method and apparatus for transmitting/receiving link status

(75) Inventor: Byoung-yue Kim, Suwon-si (KR)

Correspondence Address: ROYLANCE, ABRAMS, BERDO & GOODMAN, L.L.P., 1300 19TH STREET, N.W., SUITE 600, WASHINGTON,, DC, 20036, US

(73) Assignee: Samsung Electronics Co. Ltd.

(21) Appl. No.: 11/822,798

(22) Filed: Jul. 10, 2007

(30) Foreign Application Priority Data
Jul. 13, 2006 (KR) 10-2006-0065899

(51) Int. Cl. G01R 31/08

(52) U.S. Cl. 370/245

(57) ABSTRACT

A method and apparatus for transmitting/receiving a stored link status are provided where a link status associated with a connection status of a wireless network is stored, and the stored link status is matched to a predetermined link code SO as to generate link information. Thereafter, a frame containing the generated link information is transmitted to one or more stations connected to the wireless network. Accordingly, among a plurality of printers and host computers connected to the wireless network, if there is a printer or a host computer which cannot be connected to the wireless network, a user can determine the reason why. Therefore, the user can constantly recognize determine a link status of the plurality of printers connected to the wireless network, thereby facilitating management of the wireless network.

### CROSS-REFERENCE TO RELATED PATENT APPLICATION

This application claims the benefit under 35 U.S.C. §119(a) of Korean Patent Application No. 10-2006-0065899, filed on Jul. 13, 2006, in the Korean Intellectual Property Office, the entire disclosure of which is hereby incorporated by reference.

### BACKGROUND OF THE INVENTION

1. Field of the Invention

The present invention relates to a method and apparatus for transmitting/receiving a link status.

2. Description of the Related Art

As network environments are becoming more important, not only host computers but also peripheral devices such as printers incorporate interfaces. However, erroneous conditions relating to a peripheral device cannot be easily notified to a user because, unlike a host computer, a peripheral device (for example, a printer) may not include a device such as a monitor or a keyboard through which input and output can be performed. As a result, a problem or a cause thereof that occurs according to a link status of a station (for example, a printer) connected to a wireless network cannot be recognized by another station (for example, host computer) or by another host computer connected to a wired network. Therefore, there is no way for the user to take appropriate measures to remedy the problem.

FIG. 1 illustrates a wireless network formed by a plurality of printing devices in a local area network (LAN) environment based on the existing institute of electrical and electronics engineers (IEEE) 802.11-i standard.

Examples of the wireless network formed by the plurality of printing devices include a wireless network infrastructure in which communication is performed around an access point (AP) and an ad-hoc wireless network in which all devices communicate with one another within a network environment in the absence of a specific AP. Referring to FIG. 1, each station uses a wireless network infrastructure. Specifically, a host personal computer 1, a printer 1 and a printer 2 are stations that are connected through a wireless network, and communicate with one another through an AP. In these stations, data is transmitted and/or received after a link is formed by using a control frame and a management frame in order to participate in the wireless network, according to the IEEE 802.11-i standard.

For example, in order to find an available wireless network, a station broadcasts a probe request packet, and receives a probe response packet in response thereto. After receiving the probe response packet or only a beacon packet, the station extracts information on the available wireless network. Specifically, each station transmits a packet containing information on an authentication method based on the IEEE 802.11-i standard and a packet for requesting connection permission and receives a corresponding frame, so as to be connected to and be able to communicate through the wireless network.

In order for a station to communicate through a wireless network, multiple responses have to be transmitted and received. Specifically, a packet for requesting an available wireless network, a packet for requesting information on an authentication method, a packet for requesting connection permission, and so on, are transmitted and all responses thereto have to be received. If any one of the responses is not received, the station cannot be connected to the wireless network. In this case, the station cannot be connected to the wireless network for various reasons according to a packet type and a process carried out when a packet fails to be received. In FIG. 1, if the printer 1 and the host computer 1 are successfully connected to the wireless network, while the printer 2 cannot be connected to the wireless network, each station connected to the wireless network and a host computer 2 connected to the wireless network by wire cannot determine which station is not connected to the wireless network. Furthermore, there is no way to determine the reason why the station cannot be connected to the wireless network.

FIG. 2 illustrates a configuration of a probe frame to be transmitted on the basis of the existing IEEE 802.11-I standard. Specifically, a field, 200, is assigned with an 802.11 media access control (MAC) header. Another field, 210, is assigned with data that is to be transmitted and another field, 220, is assigned with a frame check sequence (FCS) so as to check errors. In the field 210, an item identifier, a length of data and information are repeated and the size of the data is limited so as not to exceed the size of the field, 210.

FIG. 3 illustrates a list of information describing a definition of each item based on the existing IEEE 802.11-I standard. Specifically, each item identifier is defined according to its usage, except for reserved items identifiers 7 to 15, 43 to 47, and 51 to 255 which can be assigned in order to indicate the definitions of data transmission.

Accordingly, there is a need for an improved method and apparatus for transmitting/receiving a link status for recognizing link status of stations connected on the a network.

### SUMMARY OF THE INVENTION

Exemplary embodiments of the present invention address at least the above problems and/or disadvantages and provide at least the advantages described below. Accordingly, an aspect of exemplary embodiments of the present invention is to provide a method and apparatus for transmitting/receiving a link status of a plurality of stations in a wireless network based on the IEEE 802.11-I standard and generating an integrated link information table where the generated link information table is shared by the stations so that the stations connected to the wireless network can recognize every link information.

Another aspect of exemplary embodiments of the present invention is to provide a method for transmitting a link status, the method comprising receiving a connection status of a wireless network, generating link information by matching the received connection status to a predetermined link code and transmitting a frame containing the generated link information to one or more stations connected to the wireless network.

Another aspect of exemplary embodiments of the present invention is to provide a method for transmitting a link status, the method comprising classifying a connection status of a wireless network into all possible link statuses and generating respective link codes for the classified link statuses, generating link information by matching the connection status of the wireless network to the generated link codes and transmitting a frame containing the generated link information to one or more stations connected to the wireless network.

Another aspect of exemplary embodiments of the present invention is to provide a method for receiving a link status, the method comprising receiving a frame transmitted through a wireless network from one or more stations connected to the wireless network, extracting a link code corresponding to the link information contained in the received frame and generating a link information table for each station by using the link code.

Another aspect of exemplary embodiments of the present invention is to provide a method of receiving a link status comprising receiving a frame that contains link information and is transmitted through a wireless network from one or more stations connected to the wireless network, extracting a link code corresponding to link information from the received frame and generating a link information table for each station by using the link code.

Another aspect of exemplary embodiments of the present invention is to provide an apparatus for transmitting a link status, the apparatus comprising a link code generator that classifies a connection status of a wireless network into all possible link statuses and generates respective link codes for the classified link statuses, a link information generator that generates link information by matching the link statuses of the wireless network to the generated link codes and a frame transmitter that transmits a frame containing the generated link information to one or more stations connected to the wireless network.

Another aspect of exemplary embodiments of the present invention is to provide a method of transmitting/receiving a link status, the method comprising receiving a connection status of a wireless network, generating link information by matching the received connection status to a predetermined link code, transmitting a frame containing the generated link information to one or more stations connected to the wireless network, receiving the frame transmitted through the wireless network from one or more stations connected to the wireless network, extracting a link code corresponding to the link information contained in the received frame and generating a link information table by matching the extracted link code to each station and by adding a wireless link code corresponding to the generated link information.

Another aspect of exemplary embodiments of the present invention is to provide a computer-readable medium having embodied thereon a computer program for executing the above described exemplary methods for transmitting/receiving a link status.

Another aspect of exemplary embodiments of the present invention is to provide an apparatus for transmitting/receiving a link status, the apparatus comprising a frame receiver that receives the frame transmitted through the wireless network from one or more stations connected to the wireless network, a link information checker that checks whether link information is contained in the received frame, a link code extractor that extracts a link code corresponding to the link information if the link information is contained in the received frame and a link information table generator that generates a link information table by matching the extracted link code to each station.

Another aspect of exemplary embodiments of the present invention is to provide an apparatus for transmitting/receiving a connection status, the apparatus comprising a link code generator that classifies a connection status of a wireless network into all possible link statuses and generates respective link codes for the classified link statuses, a link information generator that generates link information by matching the link statuses of the wireless network to the generated link codes, a frame transmitter that transmits a frame containing the generated link information to one or more stations connected to the wireless network, a frame receiver that receives the frame transmitted through the wireless network from one or more stations connected to the wireless network, a link code extractor that extracts a link code corresponding to link information contained in the received frame and a link information table generator that generates a link information table for each station by using the link code.

Other objects, advantages and salient features of the invention will become apparent to those skilled in the art from the following detailed description, which, taken in conjunction with annexed drawings, discloses exemplary embodiments of the invention.

### BRIEF DESCRIPTION OF THE DRAWINGS

The above and other exemplary features and advantages of certain exemplary embodiments of the present invention will become more apparent from the following description of certain exemplary embodiments thereof when taken in conjunction with the accompanying drawings in which:

FIG. 1 is a diagram illustrating a wireless network formed by a plurality of printing devices in a local area network (LAN) environment based on the existing institute of electrical and electronics engineers (IEEE) 802.11-i standard;

FIG. 2 is a diagram illustrating a configuration of a probe frame to be transmitted on the basis of the existing IEEE 802.11-i standard;

FIG. 3 is a diagram illustrating a list of information describing a definition of each item based on the existing IEEE 802.11-i standard;

FIG. 4 is a flowchart illustrating a procedure of transmitting a link status according to an exemplary embodiment of the present invention;

FIG. 5 is a flowchart illustrating a procedure of receiving a link status according to an exemplary embodiment of the present invention;

FIG. 6 is a block diagram illustrating a configuration of an apparatus for transmitting/receiving a link status according to an exemplary embodiment of the present invention;

FIG. 7 is a diagram illustrating link codes generated according to an exemplary embodiment of the present invention;

FIG. 8 is a diagram illustrating a configuration of link information generated according to an exemplary embodiment of the present invention;

FIG. 9 is a diagram illustrating a configuration of a link information table generated according to an exemplary embodiment of the present invention;

FIG. 10 is a diagram illustrating a configuration of a link information table updated according to an exemplary embodiment of the present invention; and

FIG. 11 is a diagram illustrating a process of transmitting a link information table to a station connected to one wireless network and a station connected to a separate wired network, according to an exemplary embodiment of the present invention.

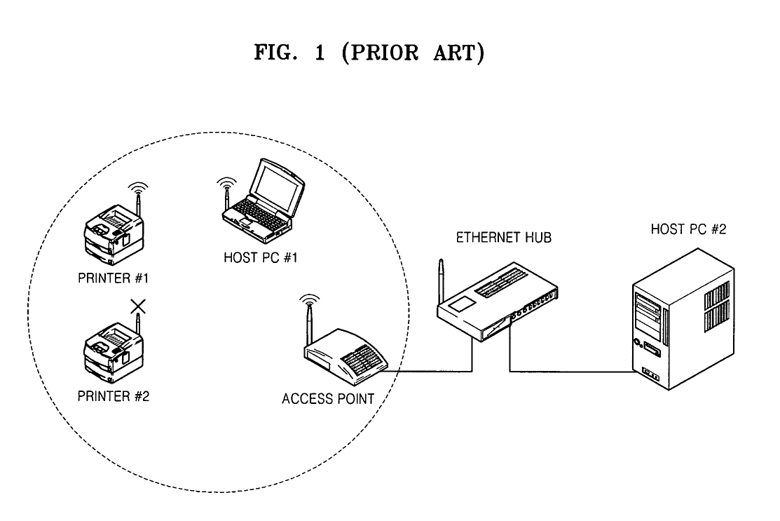

Throughout the drawings, like reference numerals will be understood to refer to like elements, features and structures.

### DETAILED DESCRIPTION OF EXEMPLARY EMBODIMENTS

The matters exemplified in this description are provided to assist in a comprehensive understanding of exemplary embodiments of the invention of the present disclosed with reference to the accompanying figures. Accordingly, those of ordinary skill in the art will recognize that various changes and modifications of the exemplary embodiments described herein can be made without departing from the scope and spirit of the claimed invention. Also, descriptions of well-known functions and constructions are omitted for clarity and conciseness.

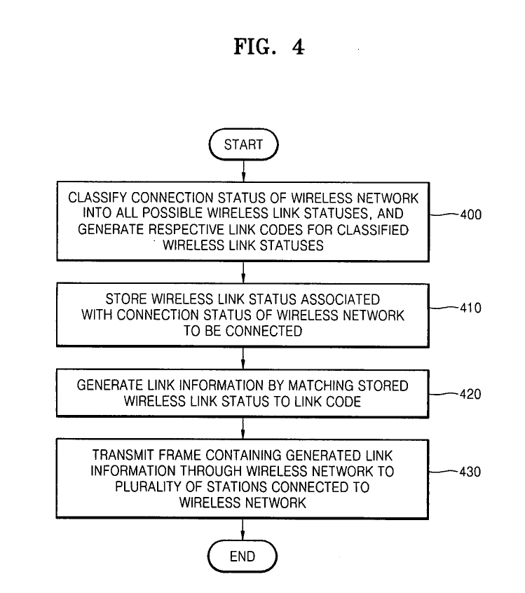

FIG. 4 is a flowchart illustrating a procedure of transmitting a link status according to an exemplary embodiment of the present invention. In operation 400, when a station attempts to be connected through a wireless network based on the IEEE 802.11-i standard, all possible connection statuses that can be formed when the station is connected through the wireless network are classified into link statuses. Then, a link code is generated by matching a classified link status to a corresponding code value.

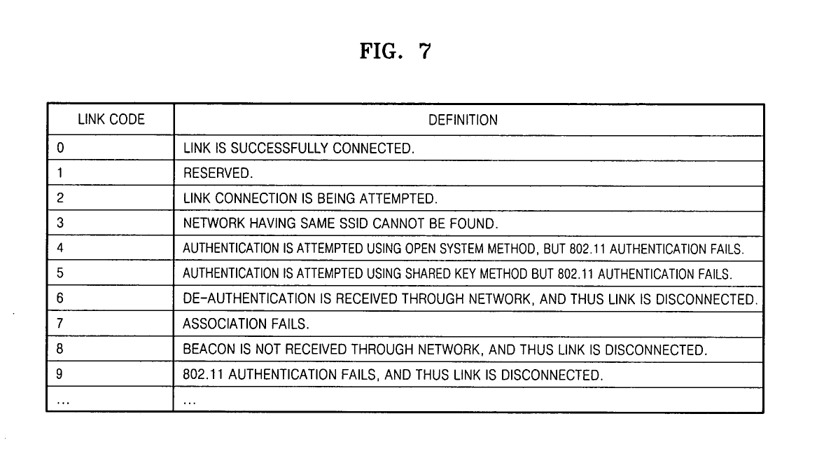

FIG. 7 is a diagram illustrating link codes generated according to an exemplary embodiment of the present invention.

According to exemplary embodiments, link statuses represent all possible connection statuses that can be formed through the wireless network connection based on the IEEE 802.11-i standard. Referring to FIG. 7, a link code 0 indicates that a link is successfully connected. A link code 2 indicates that a link connection is continuously being attempted. Although FIG. 7 shows only ten link codes ranging from 0 to 9 as an example, the number of link codes may be more than that shown in FIG. 7. Also, a link code corresponding to a possible link status may be different from that shown in FIG. 7. For example, although a status in which a link is successfully connected is indicated by the link code 0 in FIG. 7, this status may be indicated by a link code 1.

Referring to the exemplary embodiment shown in FIG. 4, in operation 410, a station stores a link status associated with a connection status of a wireless network that is to be connected. Specifically, when a station is ready to transmit a link status, the station attempts to be connected to the wireless network and stores the resultant link status.

In operation 420, link information is generated by matching the stored link status with the generated stored in operation 410 to the link code generated 420 in operation 400. Since all possible connection statuses that can be generated when a wireless connection is formed are generated in the form of link codes, 400, the wireless link status stored, 410, always corresponds to any one of the link codes.

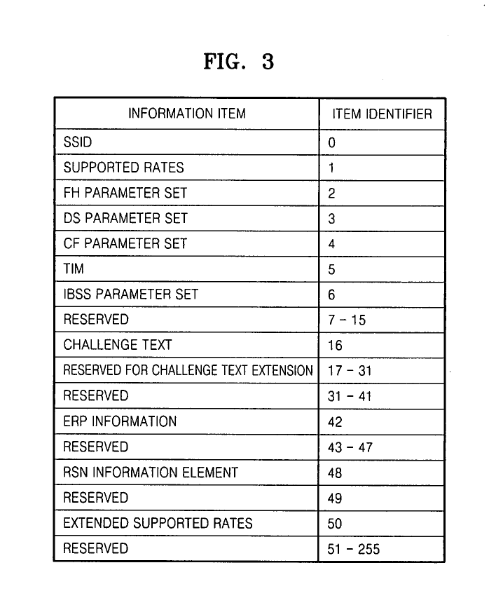

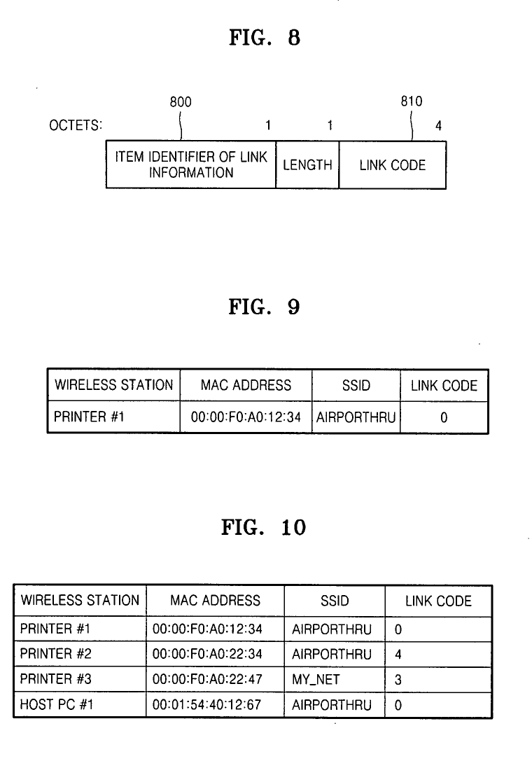

FIG. 8 illustrates a configuration of link information generated according to an exemplary embodiment of the present invention. Since the link information includes an item identifier of link information, 800, a length of data and a link code, 810, a necessary link code can be extracted from the link information so as to recognize a link status of another station. A field, 800, indicates one of a plurality of identifiers corresponding to a reserved item contained in an information list that shows the definition of each identifier based on the IEEE 802.11-i standard as shown in FIG. 3. Additionally, a field 810 indicates the link code as illustrated in FIG. 4, generated in operation 420. Referring to the exemplary embodiment described FIG. 3, examples of identifiers assigned to be reserved include 7 to 15, 43 to 47, and 51 to 255 where an identifier 7 may be assigned to the field for item identifier of link information 800. If the link code obtained in operation 420 is the link code 0, then the link code 0 may be assigned to the field 810.

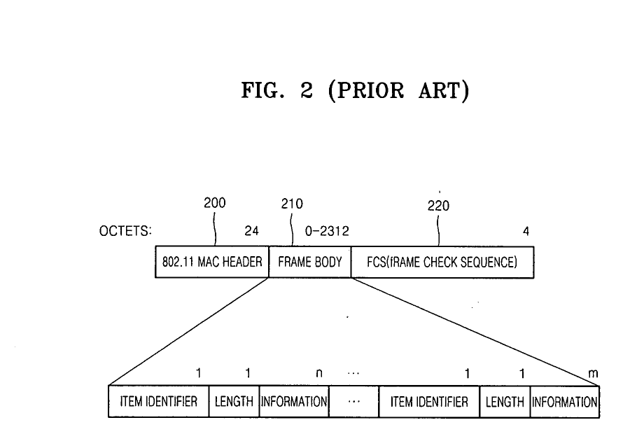

In FIG. 4, in operation 430, the station transmits a frame containing link information generated in operation 420 through a wireless network to another station connected to the wireless network. In this case, the transmitted frame may have the same frame format according to the IEEE 802.11-i standard as shown in FIG. 2, where a field 210 in FIG. 2 contains the link information identified in FIG. 8 according to the format ring to the frame format of FIG. 2.

According to an embodiment of the present invention with reference to FIG. 4, a process of generating a link code, 400, is performed prior to a process of storing a link status associated with a connection status of a wireless network that is to be connected, 410, with the station. However, in certain exemplary embodiments, the link code may be pre-generated and stored in the station such that the process of generating a link code may not be necessary.

Furthermore, since a link status may occasionally be modified in the station when the link status is modified, operations 410 to 430 may be repeated so as to constantly transmit a latest link status to another station.

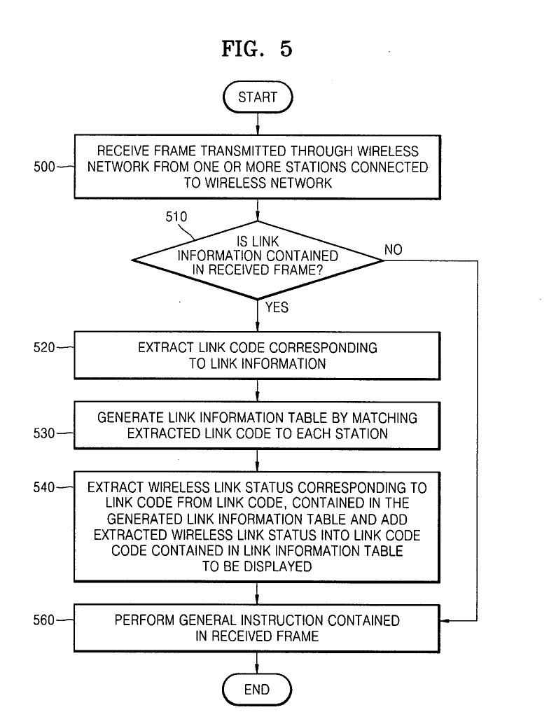

FIG. 5 is a flowchart illustrating a method of receiving a link status according to an exemplary embodiment of the present invention. Specifically, in operation 500, a frame transmitted from one or more stations connected to a wireless network may be received through the wireless network. Any one station may receive a frame transmitted from another station because, in a wireless network with a plurality of stations, each station can communicate with one or more other stations in the wireless network. Thereafter, whether the link information is contained in the received frame can be determined in operation 510.

As shown in FIG. 3, according to the current IEEE 802.11-I standard, an identifier can be designated to be reserved for a particular information item. According to an exemplary embodiment, if the received frame contains the identifier designated to be reserved and the contained identifier corresponds to link information then it can be confirmed that the received frame contains the link information. If the received frame contains the link information, the method can extract link code corresponding to link information in operation 520, otherwise, if the received frame does not contain the link information, the method performs general instructions contained in the received frame, operation 560. Thereafter, a link information table is generated by matching the extracted link code to each station, 530.

As shown in FIG. 8, since the link information includes an item identifier of link information, a length of data, and a link code, a necessary link code is extracted from the link information so as to recognize a link status of another station.

FIG. 9 illustrates a configuration of a link information table generated according to an exemplary embodiment of the present invention.

Referring to FIG. 9, the link information table can include a station that has transmitted a frame, a media access control (MAC) address that indicates the station that has transmitted a frame, a service set identifier (SSID) that distinguishes a wireless network through which a station commonly accesses the frame from another wireless network and a link code that indicates a link status. These items of information can be contained in the frame when transmitted and then the station receiving the frame can generate a link information table similar to that shown in FIG. 9 by matching the link code extracted from the received frame to each station.

Referring to FIG. 5, in operation 540, a link status corresponding to a link code is extracted from the link code contained in the generated link information table, and the extracted link status is added into the link code, thereby displaying the link information table. According to exemplary embodiments of the present invention, a user of one station can recognize a link status of another station when the link information table is displayed.

In operation 560, if the link information is not contained in the frame received in operation 510 or after the link information table is displayed in operation 540, a general instruction contained in the received frame is performed 560. According to the IEEE 802.11-h standard, general instructions contained in the received frame, 560, can comprise a probe request frame that can be transmitted and received.

According to another exemplary embodiment of the present invention, although in operation 520 it is checked whether the link information is contained in the received frame, as shown in FIG. 5, if all stations transmit the frame containing link information, a process of checking whether the link information is contained in the received frame may not be necessary.

In addition, in operation 510, to determining whether link information is contained in the received frame on one station, link information on other stations connected to the wireless network can be received through the wireless network since the frame transmitted from one or more stations is received through a wireless network.

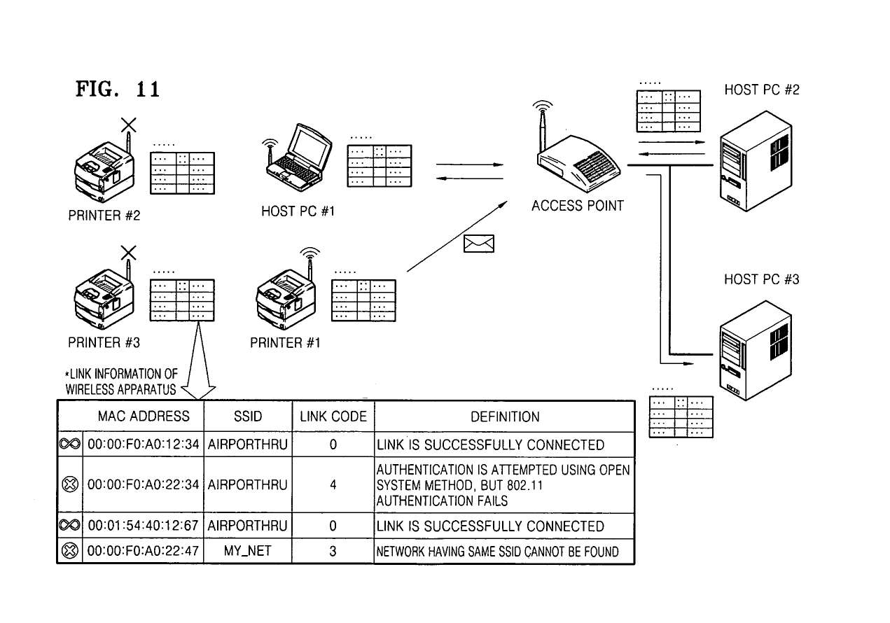

FIG. 10 illustrates a configuration of a link information table updated according to an exemplary embodiment of the present invention, which has a similar configuration as the table of FIG. 9, except that the table shown in FIG. 10 contains link information from other stations, whereas the table in FIG. 9 contains link information from only a single station. As shown in FIG. 10, all stations connected to the wireless network can be shown in the form of a single link information table. Although link information of all other stations may be generated by simultaneously receiving frames from the stations, when it is not received simultaneously, the link information may be added to the link information table as the frames are received. In addition to the link information received from other stations, the table shown in FIG. 10 can be configured to contain self-generated link information. As shown in FIG. 11, a printer 3 is an example of self-generated link information. Furthermore, a station transmits link information by using a frame whenever the link information is modified and a station receiving the frame extracts a link code from the modified frame and updates a corresponding station. Thus, the link information table constantly indicates a latest link status of each station.

All connected single stations may transmit and/or receive a link status according to exemplary embodiments of the present invention as described in FIGS. 4 and 5, respectively. For example, the stations connected with the single station can transmit as well as receive a wireless link status.

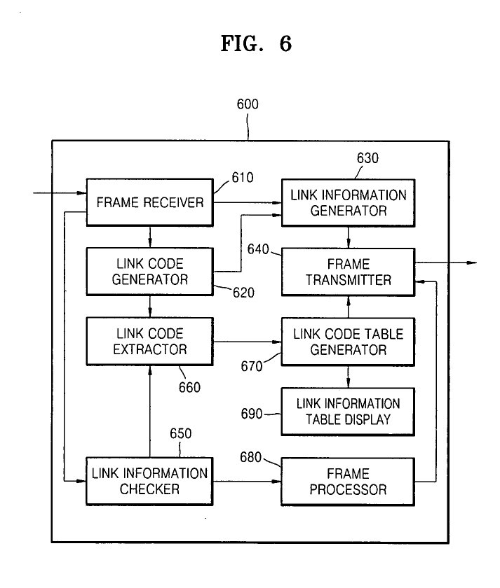

FIG. 6 is a block diagram illustrating a configuration of an apparatus for transmitting/receiving a link status according to an exemplary embodiment of the present invention.

An apparatus 600 for transmitting/receiving a link status according to an exemplary embodiment of the present invention comprises a frame receiver 610, a link code generator 620, a link information generator 630, a frame transmitter 640, a link information checker 650, a link code extractor 660, a link code table generator 670, a frame processor 680 and a link information table display 690.

Exemplary implementation of the present invention provide a method of transmitting/receiving a link status will now be described with reference to the apparatus described in FIG. 6. According to an aspect of exemplary embodiments of the present invention for transmitting a link status, a frame transmitter 640 and a frame receiver 610 transmit and receive a frame on a wireless network based on the IEEE 802.11-I standard. While repeating this process, the frame receiver 610 receives an overall frame containing link information. The link code generator 620 classifies a connection status of the wireless network into all possible link statuses by using a plurality of received frame information, and creates various link codes by matching a link code to each classified link status. The link code may be included in advance in the form of data stored in a station, in which case, the link code generator 620 may not be necessary.

The frame transmitter 640 transmits the frame through the wireless network and the frame receiver 610 receives a corresponding frame, so that a link status associated with a connection status of a wireless network can be stored. The link information generator 630 generates link information by matching the stored link status to the link code generated by the link code generator 620. In this process, an item identifier of link information is contained along with the link code based on the IEEE 802.11-i standard according to the exemplary configuration shown in FIG. 8 of the resultant link information upon generation by generator 630.

The frame transmitter 640 transmits the frame containing the link information generated by the link information generator 630 to other stations through the wireless network.

According to another aspect of exemplary embodiments of the present invention, when receiving a link status on a wireless network, the frame receiver 610 receives a frame transmitted by other stations connected to the wireless network. Initially, the link information checker 650 can check whether link information is contained in the received frame. If the link information is not contained in the received frame, the received frame is transmitted to the frame processor 680 in order to process the general content contained in the frame. Otherwise, if the link information is not contained in the received frame, the received frame may be transmitted to the link code extractor 660. The link information checker 650 may be required only when it is not certain whether the link information is contained in the received frame. Thus, the link information checker 650 may not be required if the link information is always contained in the frame. The link code extractor 660 extracts a link code corresponding to link information contained in the received frame. The link code table generator 670 generates a link information table by matching the extracted link code to each station. The link information table display 690 adds the extracted link status into a link information table formed by extracting a link status corresponding to a link code so as to display the link information table.

According to exemplary embodiments of the present invention the link information table includes information on a link status of a single station and link statuses of all stations connected to one wireless network as well as information on a self-generated link status, as shown in FIG. 10. Additionally, whenever the link information is modified, the modified information is contained in a frame and then is transmitted to a second station. As a result, the second station receives a frame containing the modified information table. Accordingly, the link information table is constantly updated to contain the modified link information whenever the frame is received.

The frame receiver 610 may receive a frame containing an instruction that requests a link information table generated by a second station connected to the same wireless network or by a second station connected by wire. When the frame receiver 610 receives this frame, the frame transmitter 640 transmits the frame containing the generated link information table to the second station connected to the same wireless network or to the second station connected by wire.

FIG. 11 illustrates a process of transmitting a link information table to a station connected to one wireless network and a station connected to a separate wired network according to an exemplary embodiment of the present invention.

The wireless network has a configuration of a wireless network infrastructure.

As described with reference to FIG. 10, stations connected to one wireless network according to an exemplary embodiment of the present invention generate a link information table in the process of transmitting/receiving a frame containing link information. When the generated link information table is requested by another station, the link information table is transmitted in response thereto. Thus, each station can share the same information table. A station disconnected from the wireless network cannot transmit/receive any data through the wireless network. However, even when a link is not formed, a management frame can be transmitted and received in a network environment based on the IEEE 802.11-I standard.

Furthermore, a host personal computer 2 and a host personal computer 3, which are connected by wire through an access point (AP), can request the link information table generated according to an exemplary embodiment of the present invention. In response to the request, a station receiving the request for the link information table transmits the requested link information table. Therefore, peripheral devices connected to the wired network can receive the link information table as shown in FIG. 11. Moreover, the link information table is transmitted to the peripheral devices connected to the wired network through an e-mail service, so that stations connected to the wireless network can recognize a link status. Although the link information table is transmitted by means of the e-mail service according to an exemplary embodiment of the present invention, the present invention is not limited to the e-mail service but applies to all communication means that can transmit the link information table while being connected to a printer. Other exemplary embodiments of the communication means may include a short message service (SMS), a multimedia messaging system (MMS) and a fax machine.

Accordingly to exemplary embodiments of the present invention, information on a link status may be shown in the form of a single table, wherein the link status indicates a connection status of a plurality of stations connected to a wireless network and the table can be shared by the plurality of stations connected to the wireless network. Thus, there is an advantage in that each station can recognize a status of another station connected to the wireless network. Additionally, information on a link status of a station can be updated whenever the link status is modified, so that the latest link status can be constantly recognized. In addition, all stations connected to the wireless network can share the same information. Thus, there is an advantage in that a user can easily manage the stations connected to the wireless network.

The above-described exemplary embodiments of an apparatus and method for transmitting/receiving link status may be recorded in computer-readable media including program instructions to implement various operations embodied by a computer. The media may also include, alone or in combination with the program instructions, data files, data structures, and the like. The media and program instructions may be those specially designed and constructed for the purposes of the present invention, or they may be of the kind well-known and available to those having skill in the computer software arts. Examples of computer-readable media include magnetic media such as hard disks, floppy disks, and magnetic tape; optical media such as CD ROM disks and DVD; magneto-optical media such as optical disks; and hardware devices that are specially configured to store and perform program instructions, such as read-only memory (ROM), random access memory (RAM), flash memory, and the like. The media may also be a transmission medium such as optical or metallic lines, wave guides, et and so on, including a carrier wave transmitting signals specifying the program instructions, data structures, et and so on. Examples of program instructions include both machine code, such as produced by a compiler, and files containing higher level code that may be executed by the computer using an interpreter. The described hardware devices may be configured to act as one or more software modules in order to perform the operations of the above-described embodiments of the present invention.

While the present invention has been shown and described with reference to particular illustrative embodiments, it is not to be restricted by the exemplary embodiments but only by the appended claims and their equivalent. It is to be appreciated that those skilled in the art can change or modify the exemplary embodiments without departing from and the scope and spirit of the present invention.

What is claimed is:

1. A method for transmitting a link status comprising:
receiving a connection status of a wireless network;
generating link information by matching the received connection status to a link code; and
transmitting a frame containing the generated link information to one or more stations connected to the wireless network.

2. The method of claim 1, wherein the receiving of the connection status comprises updating the connection status when the connection status of the wireless network is modified.

3. A method for transmitting a link status comprising:
classifying a connection status of a wireless network into at least one of a plurality of link statuses and generating respective link codes for the classified link statuses;
generating link information by matching connection statuses of the wireless network to the generated link codes; and
transmitting a frame containing the generated link information to one or more stations connected to the wireless network.

4. The method of claim 3, wherein the generating of the link information comprises updating the link information, when the connection status of the wireless network is modified by matching the modified connection status to the generated link code.

5. A method for receiving a link status comprising:
receiving a frame transmitted through a wireless network from one or more stations connected to the wireless network;
extracting a link code corresponding to the link information contained in the received frame; and
generating a link information table for each station by using the link code.

6. The method of claim 5, further comprising displaying the generated link table.

7. The method of claim 5, wherein, if the link status of any one of the stations is modified,
the receiving of the frame comprises receiving a frame containing the modified link information through the wireless network, and
the generating of the link information table comprises updating a link code of a station of which a link status is modified in the link information table into the extracted link code corresponding to the link information contained in the received frame.

8. The method of claim 5, further comprising:
receiving a request for the link information table from a station connected to a wired or wireless network; and
transmitting the link information table in response to the request.

9. An apparatus for transmitting a link status comprising:
a link code generator that classifies a connection status of a wireless network into at least one of a plurality of link statuses and generates respective link codes for the classified link statuses;
a link information generator that generates link information by matching the link statuses of the wireless network to the generated link codes; and
a frame transmitter that transmits a frame containing the generated link information to one or more stations connected to the wireless network.

10. The apparatus of claim 9, wherein, if the connection status of the wireless network is modified,
the link information generator updates link information by matching the modified connection status to the generated link code, and
the frame transmitter transmits a frame containing the generated link information to one or more stations connected to the wireless network.

11. An apparatus for receiving a link status comprising:
a frame receiver that receives the frame transmitted through the wireless network from one or more stations connected to the wireless network;
a link information checker that checks whether link information is contained in the received frame;
a link code extractor that extracts a link code corresponding to the link information if the link information is contained in the received frame; and
a link information table generator that generates a link information table by matching the extracted link code to each station.

12. The apparatus of claim 11, further comprising a link information table display that displays the generated link information table.

13. The apparatus of claim 11, wherein, if the link status of any one of the stations is modified,
the frame receiver receives a frame containing the modified link information through the wireless network, and
the link status display updates a link code of a station, of which a link status is modified, in the link information table into the extracted link code.

14. The apparatus of claim 11, wherein the frame receiver receives a frame that requests the link information table from a station connected to a wired or wireless network and the frame transmitter transmits a frame containing the link information table in response to the received frame.

15. A method for transmitting/receiving a link status comprising:
receiving a connection status of a wireless network;
generating link information by matching the received connection status to a link code;
transmitting a frame containing the generated link information to one or more stations connected to the wireless network;
receiving the frame transmitted through the wireless network from one or more stations connected to the wireless network;
extracting a link code corresponding to the link information contained in the received frame; and
generating a link information table for each station by using the link code.

16. An apparatus for transmitting/receiving a connection status comprising:
a link code generator that classifies a connection status of a wireless network into at least one of a plurality of link statuses, and generates respective link codes for the classified link statuses;
a link information generator that generates link information by matching the link statuses of the wireless network to the generated link codes;
a frame transmitter that transmits a frame containing the generated link information to one or more stations connected to the wireless network;
a frame receiver that receives the frame transmitted through the wireless network from one or more stations connected to the wireless network;
a link code extractor that extracts a link code corresponding to link information contained in the received frame; and
a link information table generator that generates a link information table for each station by using the link code.

17. A computer implemented method for transmitting a link status comprising:
receiving a connection status of a wireless network;
generating link information by matching the received connection status to a link code; and
transmitting a frame containing the generated link information to one or more stations connected to the wireless network.

18. A computer implemented method for transmitting a link status comprising:
classifying a connection status of a wireless network into at least one of a plurality of link statuses, and generating respective link codes for the classified link statuses;
generating link information by matching a connection statuses of the wireless network to the generated link codes; and
transmitting a frame containing the generated link information to one or more stations connected to the wireless network.

19. A computer implemented method for receiving a link status comprising:
receiving a frame transmitted through a wireless network from one or more stations connected to the wireless network;
extracting a link code corresponding to the link information contained in the received frame; and
generating a link information table for each station by using the link code.

20. A computer implemented method for transmitting/receiving a link status, the method comprising:
receiving a connection status of a wireless network;
generating link information by matching the received connection status to a link code;
transmitting a frame containing the generated link information to one or more stations connected to the wireless network;
receiving the frame transmitted through the wireless network from one or more stations connected to the wireless network;
extracting a link code corresponding to the link information contained in the received frame; and
generating a link information table for each station by using the link code.
